(19) United States
(12) Patent Application Publication
(10) Pub. No.: US 2006/0055462 A1
(43) Pub. Date: Mar. 16, 2006

(54) Amplifier circuit and gain control method

(75) Inventor: Yasuhiko Inagaki, Atsugi-Shi (JP)

Correspondence Address: LADAS & PARRY LLP, 224 SOUTH MICHIGAN AVENUE, SUITE 1600, CHICAGO, IL, 60604, US

(73) Assignee: Mitsumi Electric Co., Ltd.

(21) Appl. No.: 11/066,092

(22) Filed: Feb. 25, 2005

(30) Foreign Application Priority Data
Sep. 16, 2004 (JP) 2004-270370

(51) Int. Cl. H03G 3/10

(52) U.S. Cl. 330/279

(57) ABSTRACT

An amplifier circuit for controlling an output signal is disclosed. The amplifier circuit includes a comparison part for comparing the output signal with a reference voltage and outputting a result of the comparison, and an amplification part for amplifying an input signal with a gain corresponding to the result output from the comparison part.

### BACKGROUND OF THE INVENTION

1. Field of the Invention

The present invention generally relates to an amplifier circuit and a gain control method, and more particularly to an amplifier circuit and a gain control method for controlling the level of an output signal to a desired level.

2. Description of the Related Art

In an amplifier circuit for driving the load of a headphone, an earphone, or a speaker, etc., a method of clipping output voltage is employed for protecting the load from, for example, overcurrent.

FIG. 5 is a diagram showing an example of an operation of a conventional circuit.

As shown in FIG. 5, in a case where an output voltage is clipped at a desired clip level V_{clip}, the output signal has a waveform that is cut off at the clip level V_{clip}. Driving the load of a headphone, an earphone, or a speaker, etc., with the output voltage causes, for example, distortion of output audio.

Other than the method of clipping output voltage, there is a method of AGC (Automatic Gain Control) in which amplitude of output voltage is controlled to a desired level by controlling the gain according to the peak value of the output voltage.

Normally, in a conventional method such as the AGC method, the amplitude of the output voltage is controlled by linearly controlling the gain according to the peak value of the output voltage. This causes problems such as unnecessary gain control in which gain is reduced even at a portion of a signal where gain adjustment is not required.

### SUMMARY OF THE INVENTION

It is an object of the present invention to provide an amplifier circuit and a gain control method for controlling the level of output voltage to a desired range without having to execute unnecessary control.

Features and advantages of the present invention are set forth in the description which follows, and in part will become apparent from the description and the accompanying drawings, or may be learned by practice of the invention according to the teachings provided in the description. Objects as well as other features and advantages of the present invention will be realized and attained by an amplifier circuit and a gain control method particularly pointed out in the specification in such full, clear, concise, and exact terms as to enable a person having ordinary skill in the art to practice the invention.

To achieve these and other advantages and in accordance with the purpose of the invention, as embodied and broadly described herein, the invention provides an amplifier circuit for controlling an output signal, the amplifier circuit including: a comparison part for comparing the output signal with a reference voltage and outputting a result of the comparison; and an amplification part for amplifying an input signal with a gain corresponding to the result output from the comparison part.

In the amplifier circuit according to an embodiment of the present invention, the amplifier circuit may further include a first inverting amplifier part for outputting a first inverted and amplified signal to the comparison part.

In the amplifier circuit according to an embodiment of the present invention, the amplifier circuit may further include a second inverting amplifier part for outputting a second inverted and amplified signal to the comparison part, wherein the comparison part includes a first comparison part for comparing the first inverted and amplified signal with the reference voltage and outputting a first comparison result, a second comparison part for comparing the second inverted and amplified signal with the reference voltage and outputting a second comparison result, and an OR gate for outputting a logical OR between the first comparison result and the second comparison result, wherein the gain is switched in accordance with the logical OR output from the OR gate.

Furthermore, the present invention provides a gain control method for controlling an output signal, the method including the steps of: a) comparing the output signal with a reference voltage; b) outputting a result of the comparison; and c) amplifying an input signal with a gain corresponding to the result output in step b).

Furthermore, the present invention provides a gain control method for controlling an output signal, the method including the steps of: a) obtaining a first comparison result by comparing a non-inverting signal with a reference voltage; b) obtaining a second comparison result by comparing an inverting signal with the reference voltage; c) outputting a logical OR between the first comparison result and the second comparison result; and d) amplifying an input signal with a gain which is switched in accordance with the logical OR output in step c).

Other objects and further features of the present invention will be apparent from the following detailed description when read in conjunction with the accompanying drawings.

### BRIEF DESCRIPTION OF THE DRAWINGS

FIG. 1 is a circuit diagram showing a configuration of a first embodiment of the present invention;

FIG. 2 is a diagram for explaining an operation of a first embodiment of the present invention;

FIG. 3 is a circuit diagram showing a configuration of a second embodiment of the present invention;

FIG. 4 is a diagram for explaining an operation of a second embodiment of the present invention; and

FIG. 5 is a diagram for explaining an operation of a conventional circuit.

### DESCRIPTION OF THE PREFERRED EMBODIMENTS

### First Embodiment

[Configuration]

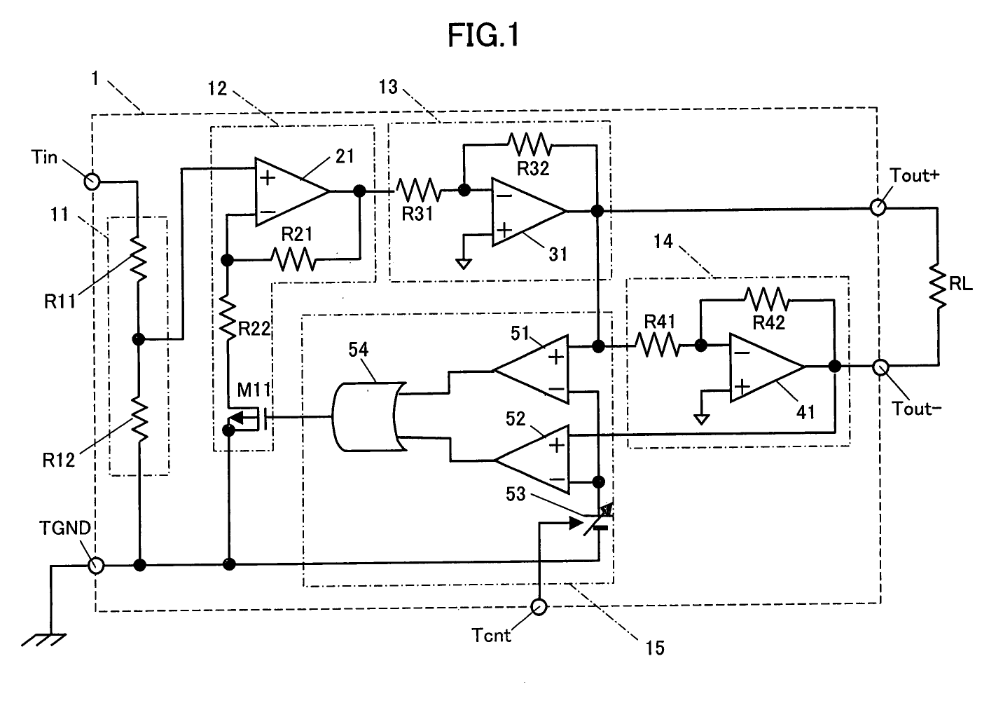

FIG. 1 is a circuit diagram showing a configuration of an amplifier circuit 1 according to a first embodiment of the present invention.

The amplifier circuit 1 of the first embodiment of the present invention amplifies an input audio signal and supplies the amplified signal to a load RL. The load RL is, for example, a speaker.

The amplifier circuit 1 includes a voltage divider circuit 11, a gain control circuit 12, an inverting amplifier circuits 13, 14, and a gain switch circuit 15. The voltage divider circuit 11 has a resistance R11 and a resistance R12 connected in series between a terminal Tᵢₙ and a constant voltage V_{com} serving as a reference voltage. The voltage divider circuit 11 divides an input audio signal supplied to the terminal Tᵢₙ in accordance with the proportion of resistance between the resistances R11 and R12 and outputs the divided input audio signal from a junction point between the resistances R11 and R12.

Then, the input audio signal divided in the voltage divider circuit 11 is supplied to the gain control circuit 12. The gain control circuit 12, which is configured as a non-inverting amplifier circuit, includes a differential amplifier circuit 21, resistances R21, R22, and a transistor M11. The input audio signal divided in the voltage divider circuit 11 is input to a non-inverting input terminal of the differential amplifier circuit 21. The resistance R21 is connected between an output terminal of the differential amplifier circuit 21 and an inverting input terminal of the differential amplifier circuit 21. Furthermore, the resistance R22 has one end connected to the inverting input terminal of the differential amplifier circuit 21 and the other end supplied with the constant voltage V_{com} via the transistor M11.

The transistor M11 is configured as, for example, a p channel MOS field effect transistor, in which the transistor M11 has a source connected to the other end of the resistance R22 and a drain and a back gate supplied with the constant voltage V_{com}. Furthermore, the transistor M11, having a gate connected to the gain switch circuit 15, executes switching according to a gain switch signal from the gain switch circuit 15.

When the transistor M11 is switched on, the inverting input terminal of the differential amplifier circuit 21 is connected to the output terminal of the differential amplifier circuit 21 via the resistance R21 and is also supplied with the constant voltage V_{com} via the resistance R22. Here, the gain A1 of the gain control circuit 12 satisfies a relation of:
A1=(R21+R22)/R22.
For example, in a case of R21=R22, A1=two times.

Furthermore, when the transistor M11 is switched off, the inverting input terminal of the differential amplifier circuit 21 is connected to the output terminal of the differential amplifier circuit 21 via the resistance R21. Here, the gain A2 of the gain control circuit 12 satisfies a relation of:
A2=1

Accordingly, the gain control circuit 12 is able to control the gains A1 and A2 by switching the transistor M11 in accordance with the switch control signal from the gain switch circuit 15.

Then, the audio signal output from the gain control circuit 12 is supplied to the inverting amplifier circuit 13.

The inverting amplifier circuit 13, which is configured as an inverting amplifier circuit, includes a differential amplifier circuit 31 and resistances R31, R32. The audio signal output from the gain control circuit 12 is supplied an inverting input terminal via the resistance R31. A non-inverting input terminal of the differential amplifier circuit 31 is supplied with the constant voltage V_{com}. The resistance R32 is connected between an output terminal of the differential amplifier circuit 31 and the non-inverting terminal of the differential amplifier circuit 31. The resistances R31 and R32 are set to satisfy a relation of (R31=R32).

The audio signal supplied from the gain control circuit 12 to the inverting amplifier circuit 13 is multiplied −1 times and output therefrom. The audio signal output from the inverting amplifier circuit 13 is supplied to an output terminal Tₒᵤₜ₊, the inverting amplifier circuit 14, and the gain switch circuit 15.

The inverting amplifier circuit 14, which is configured as an inverting amplifier circuit, includes a differential amplifier circuit 41 and resistances R41, R42. Similar to the inverting amplifier circuit 13, the resistances R41 and R42 of the inverting amplifier circuit 14 are set to satisfy a relation of (R41=R42), and the audio signal supplied from the inverting amplifier circuit 13 is multiplied −1 times and output from the inverting amplifier circuit 14.

The audio signal output from the inverting amplifier circuit 14 is output to an output terminal Tₒᵤₜ₋ and is also supplied to the gain switch circuit 15.

The gain switch circuit 15 includes comparators 51, 52, a reference voltage source 53, and an OR gate 54. The audio signal output from the inverting amplifier circuit 13 is supplied to a non-inverting input terminal of the comparator 51. A reference voltage of the reference voltage source 53 is supplied to an inverting input terminal of the comparator 51. The comparator 51 is set as a high level when the audio signal output from the inverting amplifier circuit 13 is greater than the reference voltage generated in the reference voltage source 53 and is set as a low level when the audio signal output from the inverting amplifier circuit 13 is less than the reference voltage generated in the reference voltage source 53. The output of the comparator 51 is supplied to the OR gate 54.

The audio signal output from the inverting amplifier circuit 14 is supplied to a non-inverting input terminal of the comparator 52. The reference voltage of the reference voltage source 53 is supplied to an inverting input terminal of the comparator 52. The comparator 52 is set as a high level when the audio signal output from the inverting amplifier circuit 14 is greater than the reference voltage generated in the reference voltage source 53 and is set as a low level when the audio signal output from the inverting amplifier circuit 14 is less than the reference voltage generated in the reference voltage source 53. The output of the comparator 52 is supplied to the OR gate 54.

The OR gate 54 outputs a logical OR between the output of the comparator 51 and the output of the comparator 52. The output of the OR gate 54 is supplied to the gate of the transistor M11 of the gain control circuit 12. As described above, the transistor M11 is configured as a p channel MOS field effect transistor. The transistor M11 is switched on when the output of the OR gate 54 is a low level and is switched off when the output of the OR gate 54 is a high level.

[Operation]

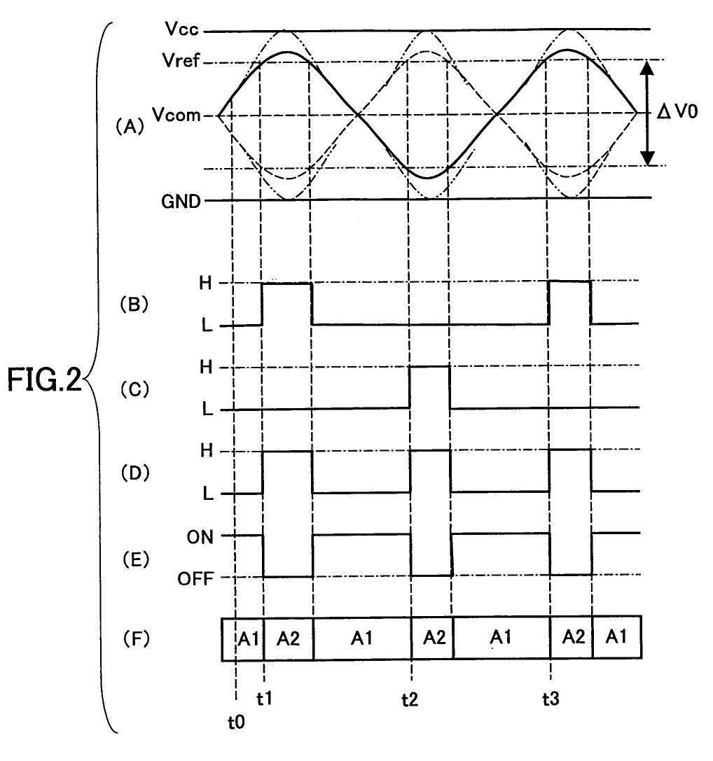

FIG. 2 is a diagram for explaining an operation of a first embodiment of the present invention. FIG. 2(A) shows waveforms of output signals of the terminals Tₒᵤₜ₊ and Tₒᵤₜ₋, FIG. 2(B) shows the output of the comparator 51, FIG. 2(C) shows the output of the comparator 52, FIG. 2(D) shows the output of the OR gate 54, FIG. 2(E) shows the switching of the transistor M11, and FIG. 2(F) shows the gain of the gain control circuit 12. In FIG. 2(A), the solid line indicates the waveform (voltage waveform) of the terminal Tₒᵤₜ₊ and the broken line indicates the waveform (voltage waveform) of the terminal Tₒᵤₜ₋.

At time t0, the output of the comparator 51 is a low level in a case where the voltage of the terminal Tₒᵤₜ₊ is less than the reference voltage V_{ref}, as shown in FIG. 2(B). The output of the OR gate 54 is a low level in a case where the output of the comparator 51 is a low level, as shown in FIG. 2(D).

In a case where the output of the OR gate is a low level, the transistor M11 is switched on. In a case where the transistor M11 is switched on, the gain of the gain control circuit 12 satisfies a relation of A1=2, as shown in FIG. 2(F).

Next, at time t1, the output of the comparator 51 is a high level (as shown in FIG. 2(B)) when the voltage of the output terminal Tₒᵤₜ₊ is greater than the reference voltage V_{ref} (as shown with the solid line in FIG. 2(A)). Since the output of the comparator 51 is a high level, the output of the OR gate 54 is a high level, as shown in FIG. 2(D).

The transistor M11 is switched off when the output of the OR gate 54 is a high level. In a case where the transistor M11 is switched off, the gain of the gain control circuit 12 satisfies a relation of A2=1, as shown in FIG. 2(F). In this case, the gain of the gain control circuit 12 is half of the gain at time t0. Accordingly, the voltage of the output terminal Tₒᵤₜ₊ can be controlled. By controlling the gain of the gain control circuit 12 to A2=1, the voltage of the output terminal Tₒᵤₜ₋ can also be controlled; thereby the voltage of the lower limit can also be controlled.

Furthermore, at time t2, the output of the comparator 52 is a high level (as shown in FIG. 2(C)) when the voltage of the output terminal Tₒᵤₜ₋ is greater than the reference voltage V_{ref} (as shown with the broken line in FIG. 2(A)). Since the output of the comparator 52 is a high level, the output of the OR gate 54 is a high level, as shown in FIG. 2(D).

The transistor M11 is switched off when the output of the OR gate 54 is a high level. In a case where the transistor M11 is switched off, the gain of the gain control circuit 12 satisfies a relation of A2=1, as shown in FIG. 2(F). In this case, the gain of the gain control circuit 12 is half of the gain at time t0. Accordingly, the voltage of the output terminal Tₒᵤₜ₋ can be controlled.

In this case, by controlling the gain of the gain control circuit 12 to A2=1, the voltage of the output terminal Tₒᵤₜ₊ (as shown with the solid line in FIG. 2(A)) can also be controlled; thereby the voltage of the lower limit can also be controlled.

Accordingly, in the first embodiment of the present invention, the amplitude of the voltage applied to the load RL can be controlled in a voltage range of ΔV0, as shown in FIG. 2(A).

Furthermore, in the first embodiment of the present invention, the gain of the gain control circuit 12 is reduced to A2 only when the voltage of the output terminal Tₒᵤₜ₊ or Tₒᵤₜ₋ is greater than the reference voltage V_{ref}. Accordingly, when the voltage of the output terminals is operating within a normal voltage range, the load RL can be driven with a normal gain of A1 and thus driven without unnecessary control.

The amplifier circuit 1 of the first embodiment of the present invention includes a terminal T_{cnt} for controlling the reference voltage V_{ref} generated in the reference voltage source 52.

### Second Embodiment

[Configuration]

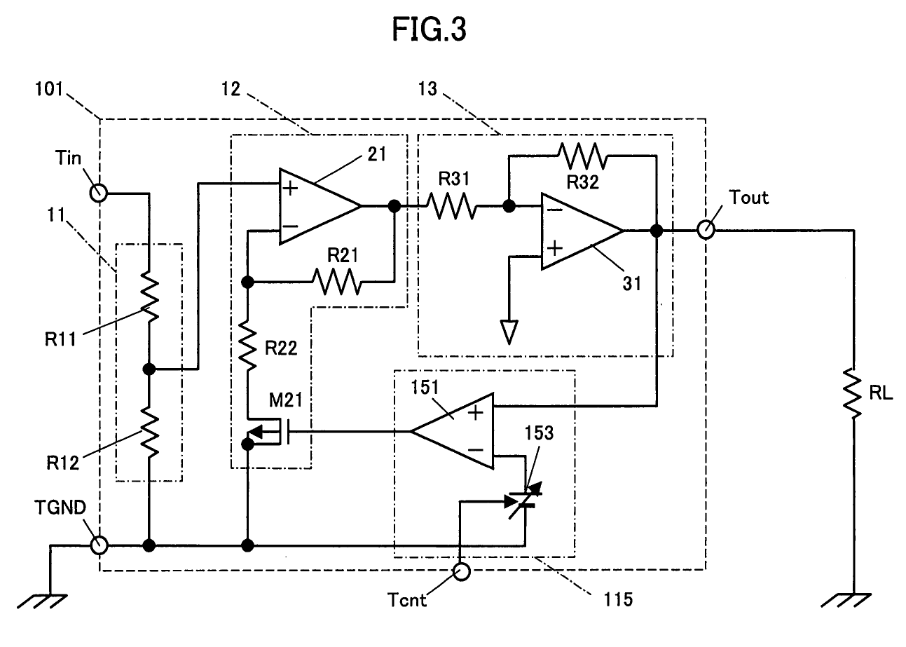

FIG. 3 is a circuit diagram showing a configuration of an amplifier circuit 101 according to a second embodiment of the present invention. In FIG. 3, like components are denoted with like numerals as of the first embodiment of the present invention shown in FIG. 1 and further description thereof is omitted.

The amplifier circuit 101 of the second embodiment of the present invention, which is configured to drive a load RL with a single polarity, includes a voltage divider circuit 11, a gain control circuit 12, an inverting amplifier circuit 13, and a gain switch circuit 115. One end of the load RL is connected to an output terminal Tₒᵤₜ and the other end is grounded. It is to be noted that voltage Vcom, which is a reference voltage for the voltage divider circuit 11 and the gain control circuit 12, is set to a ground potential.

A gain switch circuit 115 includes a comparator 151 and a reference voltage source 153. The comparator 151 has a non-inverting input terminal of the comparator 151 supplied with an output from an inverting amplifier circuit 13 and an inverting input terminal supplied with a reference voltage V_{ref} from the reference voltage source 153. The output of the comparator 151 is set as a high level when the output of the inverting amplifier circuit 13, that is, the output voltage of the output terminal Tₒᵤₜ is greater than the reference voltage V_{ref}, and is set as a low level when the output voltage of the output terminal Tₒᵤₜ is less than the reference voltage V_{ref}. The output of the comparator 151 is supplied to a gate of a transistor M11. The transistor M11 is switched off when the output of the comparator 151 is a high level, to thereby reduce the gain of the gain control circuit 12 to A2. The transistor M11 is switched on when the output of the comparator 151 is a low level, to thereby increase the gain of the gain control circuit 12 to A1.

[Operation]

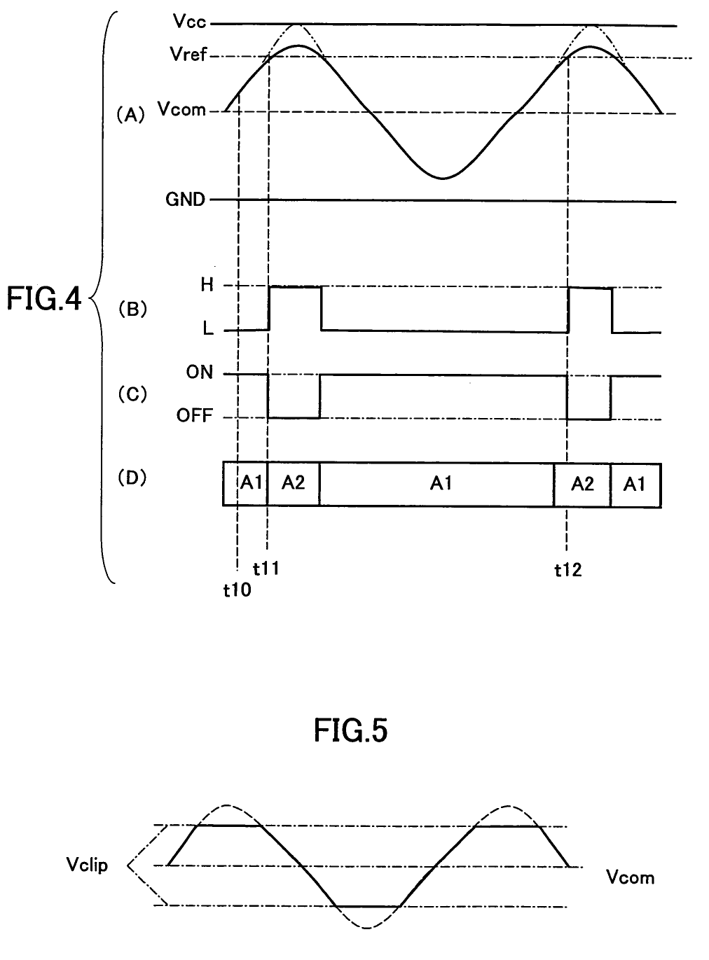

FIG. 4 is a diagram for explaining an operation of a second embodiment of the present invention. FIG. 4(A) shows waveforms of output signals of the terminals Tₒᵤₜ, FIG. 4(B) shows the output of the comparator 151, FIG. 4(C) shows the switching of the transistor M11, and FIG. 4(D) shows the gain of the gain control circuit 12.

At time t10, the output of the comparator 151 is a low level (as shown in FIG. 4(B)) in a case where the voltage of the terminal Tₒᵤₜ is less than the reference voltage V_{ref}, as shown in FIG. 4(A). In the case where the output of the comparator 151 is a low level, the transistor M11 is switched on, as shown in FIG. 4(C). In the case where the transistor M11 is switched on, the gain of the gain control circuit 12 is a normal gain of A1=2, as shown in FIG. 4(D).

Next, at times t11 and t12, the output of the comparator 151 is a high level (as shown in FIG. 4(B)) in a case where the voltage of the terminal Tₒᵤₜ is greater than the reference voltage V_{ref}, as shown in FIG. 4(A). In the case where the output of the comparator 151 is a high level, the transistor M11 is switched off, as shown in FIG. 4(C). In the case where the transistor M11 is switched off, the gain of the gain control circuit 12 is a gain of A2=1, as shown in FIG. 4(D). In this case, the gain of the gain control circuit 12 is half of the gain at time t10. Accordingly, the voltage of the output terminal Tₒᵤₜ can be controlled, as shown in FIG. 4(A).

Further, the present invention is not limited to these embodiments, but variations and modifications may be made without departing from the scope of the present invention.

The present application is based on Japanese Priority Application No. 2004-270370 filed on Sep. 16, 2004, with the Japanese Patent Office, the entire contents of which are hereby incorporated by reference.

What is claimed is:

1. An amplifier circuit for controlling an output signal, the amplifier circuit comprising:
a comparison part for comparing the output signal with a reference voltage and outputting a result of the comparison; and
an amplification part for amplifying an input signal with a gain corresponding to the result output from the comparison part.

2. The amplifier circuit as claimed in claim 1, further comprising:
a first inverting amplifier part for outputting a first inverted and amplified signal to the comparison part.

3. The amplifier circuit as claimed in claim 2, further comprising:
a second inverting amplifier part for outputting a second inverted and amplified signal to the comparison part;
wherein the comparison part includes a first comparison part for comparing the first inverted and amplified signal with the reference voltage and outputting a first comparison result, a second comparison part for comparing the second inverted and amplified signal with the reference voltage and outputting a second comparison result, and an OR gate for outputting a logical OR between the first comparison result and the second comparison result,
wherein the gain is switched in accordance with the logical OR output from the OR gate.

4. A gain control method for controlling an output signal, the method comprising the steps of:
a) comparing the output signal with a reference voltage;
b) outputting a result of the comparison; and
c) amplifying an input signal with a gain corresponding to the result output in step b).

5. A gain control method for controlling an output signal, the method comprising the steps of:
a) obtaining a first comparison result by comparing a non-inverting signal with a reference voltage;
b) obtaining a second comparison result by comparing an inverting signal with the reference voltage;
c) outputting a logical OR between the first comparison result and the second comparison result; and
d) amplifying an input signal with a gain which is switched in accordance with the logical OR output in step c).
